(19) United States
(12) Patent Application Publication
(10) Pub. No.: US 2025/0077746 A1
(43) Pub. Date: Mar. 6, 2025

(54) Method and System for Generating a Resilience Analysis of a Real-world System

(71) Applicant: Resilience Analytics, LLC, Manassas, VA (US)

(72) Inventors: Joshua Jordan Trump, Blacksburg, VA (US); Eugene Linkov, Newton, MA (US)

(21) Appl. No.: 18/818,389

(22) Filed: Aug. 28, 2024

Related U.S. Application Data
(60) Provisional application No. 63/535,882, filed on Aug. 31, 2023.

(51) Int. Cl. G06F 30/27

(52) U.S. Cl. CPC G06F 30/27

(57) ABSTRACT

Embodiments generate a resilience analysis of a real-world system. One such embodiment constructs a network graph representing a real-world system for providing function(s) by generating node(s) corresponding to the function(s) and generating edge(s). Each of the edge(s) links a pair of the node(s) and represents a causal dependency between respective functions corresponding to the pair of the node(s). In turn, via a first model, based on the network graph, configuration(s) of the real-world system are simulated by modifying a configuration of a function corresponding to a node of the node(s) or a causal dependency corresponding to an edge of the edge(s). Then, via the first model, based on the simulating, a resilience analysis of the real-world system is generated.

### RELATED APPLICATION

This application claims the benefit of U.S. Provisional Application No. 63/535,882, filed on Aug. 31, 2023. The entire teachings of the above application are incorporated herein by reference.

### BACKGROUND

Over time, real-world systems, such as infrastructure systems, have become more complex and interconnected. However, current approaches for stress testing real-world systems remain inadequate.

### SUMMARY

A particular area of inadequacy for existing stress testing methodologies is a failure to scale as a real-world system becomes larger and more interconnected. Embodiments include a method, system, and computer program product that provide a tiered approach to assessing both risk and resilience of real-world systems. Instead of starting with a specific threat scenario and focusing on vulnerabilities at a component level as in current approaches, embodiments employ a threat-agnostic approach that evaluates a real-world system's structure and interdependencies to assess how the system performs under degraded conditions. Embodiments thus provide a scalable methodology with maximum accessibility for a range of users. For example, embodiments enable analyses of intricate and interconnected real-world systems, which analyses are too complex to be performed by the human mind as a practical matter.

An example embodiment is directed to a computer-implemented method for generating a resilience analysis of a real-world system, such as a hospital or other healthcare system, an airport, a supply chain, or a transportation or distribution (e.g., energy or water distribution) network, among other examples. In an embodiment, the real-world system may include physical components. To begin, the method constructs a network graph representing a real-world system for providing function(s) by generating node(s) corresponding to the function(s) and generating edge(s). Each of the edge(s) links a pair of the node(s) and represents a causal dependency between respective functions corresponding to the pair of the node(s). In turn, the method simulates, via a first model, based on the network graph, configuration(s) of the real-world system by modifying a configuration of a function corresponding to a node of the node(s) or a causal dependency corresponding to an edge of the edge(s). The method then generates, via the first model, based on the simulating, a resilience analysis of the real-world system. In an embodiment, the first model is trained with data representing real-world system(s) having common element(s) to the real-world system.

In another embodiment, the method further includes identifying, via the first model, based on the resilience analysis, modification(s) to the real-world system to improve resilience. According to one such embodiment, the method further includes generating a visualization of one of the modification(s) to the real-world system. Further, in yet another embodiment, the modification(s) to the real-world system are identified based on user-defined criteria including cost and/or prioritizing one or more function(s) of the function(s). In an embodiment, the method further includes determining, based on the user-defined criteria, a prioritized sequence of the modification(s) to the real-world system. According to one such embodiment, the method further includes causing one of the modification(s) to be applied to the real-world system. In another embodiment, the modification(s) include a service-level modification and/or an asset-level modification.

Further, in yet another embodiment, the generating, via the first model, based on the simulating, the resilience analysis of the real-world system includes determining, via the first model, resilience score(s). The resilience score(s) represent a capacity of the real-world system to absorb the failure of one of the function(s), a capacity of the real-world system to recover from the failure of one of the function(s), and/or a capacity of the real-world system to adapt to the failure of one of the function(s).

According to an embodiment, the node(s) represent resource(s) associated with the function(s). In one such embodiment, the resource(s) include physical resources, digital resources (such as cyber resources, among other examples), and/or personnel resources.

In an embodiment, the method further includes identifying, via a second model, external drivers and/or causal dependency(ies) between the driver(s) and corresponding function(s) of the function(s). The method then generates node(s) corresponding to the external driver(s) identified. In turn, the method generates edge(s) corresponding to the causal dependency(ies) identified. The method also modifies the network graph to incorporate the node(s) generated and edge(s) generated. According to another embodiment, the external driver(s) include environmental-based drivers, transport-based drivers, econometric drivers, energy-based drivers, cyber-based drivers, and/or commodity-based drivers. The econometric drivers may include social-based drivers and/or personnel-based drivers, among other examples. Further, in yet another embodiment, the identifying includes executing, via the second model, search function(s) on respective causal network(s) contained in a repository.

According to an embodiment, one of the configuration(s) of the real-world system includes a disruption to a first function of the function(s). The disruption causes a failure of a second function of the function(s).

In another embodiment, one of the configuration(s) of the real-world system includes distinct operational condition(s) of the real-world system including a system workload and/or demand for a function.

Further, in yet another embodiment, the first model includes a system dynamics model, a graph theory model, a Bayesian network model, and/or an agent-based model.

In an embodiment, the first model includes a machine learning (ML) model and/or an artificial intelligence (AI) model.

Another example embodiment is directed to a computer-based system for generating a resilience analysis of a real-world system. The system includes a processor and a memory with computer code instructions stored thereon. In such an embodiment, the processor and the memory, with the computer code instructions, are configured to cause the system to implement any embodiments, or combination of embodiments, described herein.

Yet another example embodiment is directed to a non-transitory computer program product for generating a resilience analysis of a real-world system. The computer program product includes a computer-readable medium with computer code instructions stored thereon. The computer code instructions are configured, when executed by a processor, to cause an apparatus associated with the processor to implement any embodiments, or combination of embodiments, described herein.

It is noted that embodiments of the method, system, and computer program product may be configured to implement any embodiments, or combination of embodiments, described herein.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 is a flowchart of a method for generating a resilience analysis of a real-world system according to an embodiment.

FIG. 2 is a process diagram of a three-tiered approach to integrated risk/resilience stress testing for critical infrastructure, according to an embodiment.

FIG. 3 is a block diagram showing further details of the three-tiered approach of FIG. 2, according to an embodiment.

FIG. 4 is a diagram illustrating methodologies for the three-tiered approach of FIG. 2, according to an embodiment.

FIG. 5 is an overview of a framework for Tier 3 asset-level resilience analysis, according to an embodiment.

FIG. 6 is an example of relationships in a network according to an embodiment.

FIG. 7 depicts examples of third-party/external data regarding network relationships, according to an embodiment.

FIG. 8 illustrates stress testing and resilience planning for an example network, according to an embodiment.

FIG. 9A illustrates an example loan portfolio risk analysis, according to an embodiment.

FIG. 9B illustrates an example of network modeling, according to an embodiment.

FIG. 9C illustrates an example of automatic discovery of external drivers, according to an embodiment.

FIG. 9D illustrates an example of stress testing and resilience planning, according to an embodiment.

FIG. 10 is an overview of determining critical functions of a system, according to an embodiment.

FIG. 11 illustrates data integration for asset-level resilience analysis and assessment, according to an embodiment.

FIG. 12 illustrates network modeling for asset-level resilience analysis and assessment, according to an embodiment.

FIG. 13 illustrates automatic discovery of external drivers for asset-level resilience analysis and assessment, according to an embodiment.

FIG. 14 illustrates stress testing a completed model, according to an embodiment.

FIG. 15A illustrates generating resilience strategies, according to an embodiment.

FIG. 15B illustrates optional identification of critical assets, according to an embodiment.

FIG. 16A illustrates visualization of results, according to an embodiment.

FIG. 16B depicts an example interface according to an embodiment.

FIG. 17 is a schematic view of a computer network in which embodiments may be implemented.

FIG. 18 is a block diagram illustrating an example embodiment of a computer node in the computer network of FIG. 17.

### DETAILED DESCRIPTION

A description of example embodiments follows.

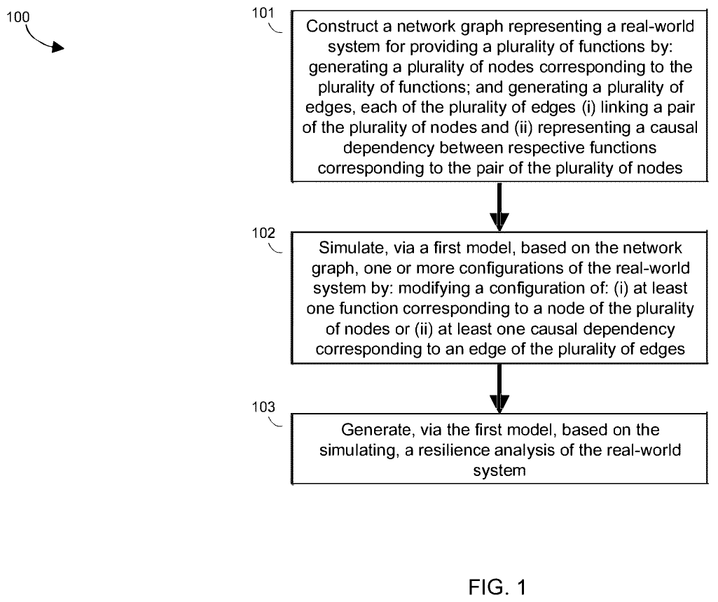

FIG. 1 is a flowchart of a method 100 for generating a resilience analysis of a real-world system according to an embodiment. The method 100 is a computer-implemented method performed by a processor.

The method 100 begins at step 101 by constructing a network graph representing a real-world system for providing function(s) by generating node(s) corresponding to the function(s) and generating edge(s). Each of the edge(s) links a pair of the node(s) and represents a causal dependency between respective functions corresponding to the pair of the node(s). To continue, at step 102, the method simulates, via a first model, based on the network graph, configuration(s) of the real-world system by modifying a configuration of a function corresponding to a node of the node(s) or a causal dependency corresponding to an edge of the edge(s). Then at step 103, the method generates, via the first model, based on the simulating (102), a resilience analysis of the real-world system.

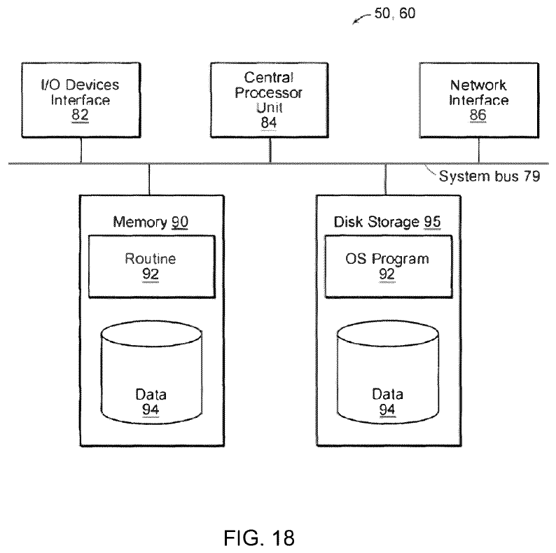

As noted, the method 100 is computer-implemented and, as such, the functionality and effective operations, e.g., the constructing (101), simulating (102), and generating (103), are automatically implemented by one or more digital processors. Moreover, the method 100 can be implemented using any computer device or combination of computing devices known in the art. Among other examples, the method 100 can be implemented using computer(s)/device(s) 50 and/or 60 described hereinbelow in relation to FIGS. 18 and 19.

In an embodiment of the method 100, the first model is trained with data representing real-world system(s) having common element(s) to the real-world system.

In another embodiment, the method 100 further includes identifying, via the first model, based on the resilience analysis, modification(s) to the real-world system to improve resilience. According to one such embodiment, the method 100 further includes generating a visualization of one of the modification(s) to the real-world system. Further, in yet another embodiment of the method 100, the modification(s) to the real-world system are identified based on user-defined criteria including cost and/or prioritizing one or more function(s) of the function(s). In an embodiment, the method 100 further includes determining, based on the user-defined criteria, a prioritized sequence of the modification(s) to the real-world system. According to one such embodiment, the method 100 further includes causing one of the modification(s) to be applied to the real-world system. In another embodiment of the method 100, the modification(s) include a service-level modification and/or an asset-level modification.

Further, in yet another embodiment of the method 100, the generating (103) includes determining, via the first model, resilience score(s). The resilience score(s) represent a capacity of the real-world system to absorb the failure of one of the function(s), a capacity of the real-world system to recover from the failure of one of the function(s), and/or a capacity of the real-world system to adapt to the failure of one of the function(s).

According to an embodiment of the method 100, the node(s) represent resource(s) associated with the function(s). In one such embodiment of the method 100, the resource(s) include physical resources, digital resources (such as cyber resources, among other examples), and/or personnel resources.

In an embodiment, the method 100 further includes identifying, via a second model, external drivers and/or causal dependency(ies) between the driver(s) and corresponding function(s) of the function(s). The method 100 then generates node(s) corresponding to the external driver(s) identified. In turn, the method 100 generates edge(s) corresponding to the causal dependency(ies) identified. The method 100 also modifies the network graph to incorporate the node(s) generated and edge(s) generated. According to another embodiment of the method 100, the external driver(s) include environmental-based drivers, transport-based drivers, econometric drivers, energy-based drivers, cyber-based drivers, and/or commodity-based drivers. The econometric drivers may include social-based drivers and/or personnel-based drivers, among other examples. Further, in yet another embodiment of the method 100, the identifying includes executing, via the second model, search function(s) on respective causal network(s) contained in a repository.

According to an embodiment of the method 100, one of the configuration(s) of the real-world system includes a disruption to a first function of the function(s). The disruption causes a failure of a second function of the function(s).

In another embodiment of the method 100, one of the configuration(s) of the real-world system includes distinct operational condition(s) of the real-world system including a system workload and/or demand for a function.

Further, in yet another embodiment of the method 100, the first model includes a system dynamics model, a graph theory model, a Bayesian network model, and/or an agent-based model.

In an embodiment of the method 100, the first model includes a ML model and/or an AI model.

### INTRODUCTION

More than ever, society is dependent upon complex and interconnected infrastructure to fulfill all the functions of modern life. Infrastructure centralization and interconnectivity has harnessed efficiencies that provide faster, less expensive, and more advanced service capabilities for developed and developing nations alike. Yet, the same nested network dependencies that enable advanced infrastructural services equally enable systemic failure-fostering extensive societal losses more debilitating than in decades past. Where the trend towards nested infrastructure dependencies is only accelerating, a critical question has emerged: what can societies do to better safeguard themselves from systemic risks affecting infrastructure?

Many national and international organizations have grappled with the need to anticipate catalysts that may degrade or destroy various forms of critical infrastructure. For example, the United Nations' (UN) Sustainable Development Goal #9 (SDG 9) calls to “build resilient infrastructure, meaning decision-makers must seek to create infrastructure that can “resist, absorb, accommodate to and recover from the effects of a hazard in a timely and efficient manner”. Target D of the Sendai Framework complements this SDG, calling for the substantial reduction of disaster damage to critical infrastructure. Other documents such as the 2022 UN Global Assessment Report (GAR), have further highlighted the need for shifting toward a more holistic approach to address the systemic nature of risk, particularly given a region's exposure to compounding vulnerabilities. In response to this international imperative for analyzing the intricate interaction of systemic risk and infrastructure, stress testing has been offered as a response.

A necessary first step to address this question must include an analysis of the single-points-of-failure that arise when systems affecting the infrastructure system (environment, society, etc.) operate beyond normal conditions. Sometimes called “stress testing,” this methodology seeks to identify the conditions where infrastructure system failure is possible. A “stress” as it refers to an episodic or prolonged disruptive event, has previously relied upon scenario analyses for validation. In the documents released by the Dent, stress testing is calibrated on the conditions of “severe but plausible” events and the tolerance of organizations for disruptions, assuming the event will happen.

Borrowing concepts from medicine and engineering, stress testing has emerged as one of the prominent regulatory mechanisms in the financial and nuclear industries after catastrophes. In these applications, stress testing identifies risks that must be avoided, such as the collapse of the housing market or nuclear reactor meltdown. These risk-focused stress test exercises are important to understand how to prepare and absorb a similar shock, but as systems become more intricate, their levels and modes of disruption increase and spread. Stress testing must evolve to not only incorporate these risks and determine how to withstand their impacts, but to overcome them.

Existing risk stress testing methodologies do not scale well as the system becomes larger and more interconnected. An example of a system that is too large to model in this fashion is the global supply chain, in which modeling every component is not feasible. In critical infrastructure, such component level stress-related analysis may be especially limited because of the interconnected nature of complex infrastructure systems often affected by compounding threats resulting in cascading failures. However, as critical infrastructure becomes increasingly interconnected, it is becoming imperative to develop methods that can scale to understand how infrastructural systems collapse and recover in the midst of crises.

Unlike risk assessments that start with a specific threat scenario and focus on vulnerabilities at a component level, resilience analytics favors a more threat-agnostic approach—evaluating the structure and interdependencies of a system to assess how the system performs under degraded conditions. Implicit within resilience are considerations of how systems with degraded functionality (disrupted nodes and/or severed/degraded links) can recover and adapt after a range of potential stressors-particularly those akin to a “one-hundred-year event.” For disciplines from economics and finance to physical infrastructure, both methodologies are necessary and useful, yet systems analysis using resilience analytics has only recently become a more commonly requested practice.

To both (a) establish a method to stress test resilience of critical infrastructure, and (b) scale that methodology to maximize its accessibility for a range of users, this document describes a tiered approach that guides the assessment of both risk and resilience that is under development by UN Office for Disaster Risk Reduction (UNDRR). For any infrastructure resilience stress test, it is imperative to balance customizability of the analysis (analyzing conditions as close to the real-world as possible) against practicality (the time and resource constraints to conduct such assessment for a range of stakeholders). In turn, a tiered approach provides transparency and structure to infrastructure stress testing, while utilizing available quantitative and qualitative information to inform where and how infrastructure systems may buckle under pressure.

### Critical Infrastructure

The term “critical infrastructure” includes, but is not limited to, any transportation, utility, or engineered system, among other examples. Evaluation of such a broad range of physical infrastructure and modes of engineering has led to many applications of stress testing. Risk-based tools exist, such as stress testing for water, transportation, telecommunication, and energy. Some of these stress tests consider critical infrastructure in isolation from other infrastructure. For example, prior work stress tests hydro-electric infrastructure against financial, climate, and geophysical shocks. Other prior work applied stress testing to airports against a range of disturbances to assess resilience. However, a combined approach to evaluate several sectors has also been discussed in the past decade. These combined approaches begin to analyze how components of critical infrastructure fail in disruptive events such as the Texas Freeze. Previous work has called for the need of resilience-based stress testing tools to assess critical infrastructure systems' abilities to respond to increasingly severe disruptive events, underscoring the importance of how critical infrastructures are interdependent.

Stress testing has been operationalized by assessing the infrastructure's ability to respond to a specified threat scenario at a component level. For example, the European Commission's STREST project assessed critical infrastructure components as a system against a variety of disruptors. A changing climate presents a range of environmental threat scenarios, which denotes the need for stress testing tools that assess climate's impact on critical infrastructure. The World Bank Group created a risk-based stress test tool that functions as a cost-benefit analysis of critical infrastructure components' response to climate-induced shocks and stresses. Monte Carlo algorithms, game theory and graph theory, and the creation of various indices to tabulate vulnerable assets are a few examples of the methods that have been formed to evaluate stress testing for critical infrastructure.

### Stress Testing for Resilience

The literature presents numerous applications of stress testing in different fields, but the focus is primarily on stress testing for risk. The goal is to gain understanding on how the system responds to different amounts of disruptions. Comparable to risk assessment and management where risk is quantified in comparison to acceptable performance thresholds, risk stress testing increases levels of stress to identify points of systemic failure. A system under small and acceptable stress should perform well. Yet, as the amount of stress imposed across interconnected nodes and links increases, far more resources are required to sustain system functions and performance. At a given point, the stress placed upon the system becomes too great to bear, saturates across its critical functions, and collapses. The stress/strain relationship developed in materials science has been generalized for infrastructure for construction safety in general as well as disaster response in particular.

Stress testing is about understanding the point at which the system is unable to cope with the amount of load imposed on it. Through such improved understanding, stakeholders can reduce system bottlenecks that hasten collapse, or identify avenues to adapt during disruption to (a) extend the system's lifespan and/or (b) soften the degradation process via a gradual rather than abrupt decline.

Resilience terminology has been used in multiple studies, but its connection to the ability of the systems to recover and adapt from threats at a cross-domain level is rarely addressed. Tabletop exercises and scenario building can be used for identifying common point of failures to different threats and concurrencies, assessing escalation points that could cause “knockout” disruptions across sectors. A direct consequence of this approach is in development of resilience in the financial industry, for which stress testing has been adopted to support the capacity to recover from disruptions in capital markets. Recovery was analyzed by evaluating post-disruption contingency plans from low-probability, high-risk shocks in automotive manufacturing. Specific companies have become more concerned with stress testing in response to COVID-19 and import/export debacles, leading to measures to quantify supply chain resilience. Similarly, the U.S. Department of Energy has begun stress testing the network of electrical supply chains to evaluate the response and likelihood of catastrophic failure.

### Tiered Methodology for Resilience Stress Testing

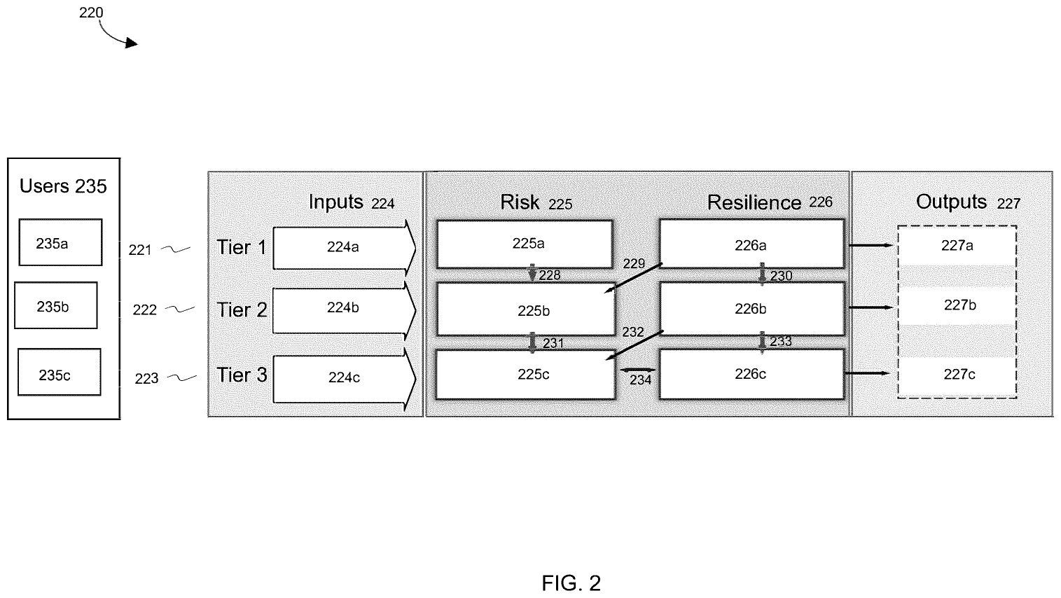

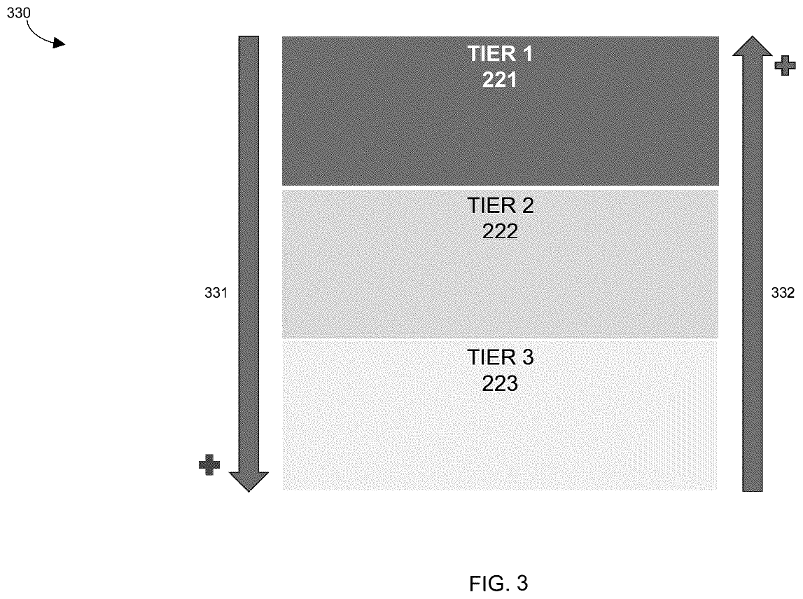

Tiered assessment approaches have been applied to risk management in various applications in order to make a transparent, repeatable, and scientifically-informed governance process that aids regulatory evaluation. Prior work has proposed to extend a tiered risk analytics approach towards resilience, but operationalization and application of this proposal are limited at best. It was argued that extending risk tiers towards resilience requires evaluation of different disruption scenarios, but stopped short of devising a stress testing approach. The approach described herein, as well as in more detail hereinbelow with respect to FIG. 2, builds and improves upon previous approaches by specifically operationalizing combined risk and resilience stress testing. Scaling from least to greatest analytical requirements—and, likewise, least to greatest granularity in evaluating infrastructure system performance under stress—the tiers, as described herein, as well as in additional detail hereinbelow with respect to FIG. 3, include:
a) Tier 1 is a screening-level assessment framing critical system functions and analyzing changes in system connectivity in response to shocks and stressors.
b) Tier 2 utilizes simplified system models to understand and quantify connections across various domains and their impacts on critical system functions.
c) Tier 3 utilizes advanced modeling techniques, such as network science, ML, and/or AI, among other examples, to further assess changes in interconnected networks in response to random and targeted threats and attack scenarios.

FIG. 2 is a process diagram 220 of a tiered approach to integrated risk/resilience stress testing for critical infrastructure, according to an embodiment. As shown in FIG. 2, stress testing uses inputs 224, performs testing for risk 225 and resilience 226, and produces outputs 227. Further, stress testing includes Tier 1, Tier 2, and Tier 3, at 221, 222, and 223, respectively. Tier 1 stress testing at 221 may be performed by users 235a, such as policy analysts and/or generalists, etc. To continue, Tier 1 stress testing 221 uses inputs 224a, which may be provided by, e.g., policy analysts, and may include, e.g., qualitative information and/or component data. Stress testing risk 225a at Tier 1 may include, e.g., developing scenarios for shocks and stresses affecting specific vulnerabilities. Likewise, stress testing resilience 226a at Tier 1 may include, e.g., identifying critical functions of systems and cascading failures. Outputs 227a generated at Tier 1 may include, e.g., improvements to fortify a system or make the system more robust, such as “quick win” improvements.

Continuing with FIG. 2, Tier 2 stress testing at 222 may be performed by users 235b, such as risk assessors, engineers, and/or decision analysts, etc. Tier 2 stress testing 222 uses inputs 224b, which may be provided by, e.g., risk and/or decision analysts, and may include, e.g., data about system structure and/or connectivity. Stress testing risk 225b at Tier 2 may include, e.g., for each domain, separately assessing risk of component failure under a stress scenario. As shown by arrow 228, stress testing risk 225b at Tier 2 may build on stress testing risk 225a performed at Tier 1. To continue, stress testing resilience 226b at Tier 2 may include, e.g., identifying connections across multiple system domains that are difficult to recover. As shown by arrows 229 and 230, stress testing risk 225b and resilience 226b at Tier 2, respectively, may be informed by and/or leverage data generated by stress testing resilience 226a at Tier 1, such as previously identified critical functions of systems and cascading failures. Outputs 227b generated at Tier 2 may include, e.g., a system-wide resilience strategy.

Again with respect to FIG. 2, Tier 3 stress testing at 223 may be performed by users 235c, such as specialists and/or modelers, etc. Tier 3 stress testing 223 uses inputs 224c, which may be provided by, e.g., network specialists, and may include, e.g., detailed system information and/or advanced data. Stress testing risk 225c at Tier 3 may include, e.g., advance probabilistic risk assessment across multiple domains and/or compounding threats. As shown by arrow 231, stress testing risk 225c at Tier 3 may build on stress testing risk 225b performed at Tier 2. To continue, stress testing resilience 226c at Tier 3 may include, e.g., employing network science and/or ML and AI techniques to assess failures in interconnected networks. As shown by arrows 232 and 233, stress testing risk 225c and resilience 226c at Tier 3, respectively, may be informed by and/or leverage data generated by stress testing resilience 226b at Tier 2, such as previously identified connections across multiple system domains that are difficult to recover. Further, as shown by arrow 234, stress testing risk 225c and resilience 226c at Tier 3 may be performed iteratively, with results from the latter being used to perform a subsequent iteration of the former, and vice versa. Outputs 227c generated at Tier 3 may include, e.g., targeted changes and/or interventions.

In an embodiment, Tier 1, 2, and/or 3 stress testing 221, 222, and/or 223 may be performed by, e.g., method 100 (FIG. 1).

FIG. 3 is a block diagram 330 showing further details of the tiered approach of FIG. 2, according to an embodiment. As shown in FIG. 3, downwards arrow 331 indicates that analytical complexity and/or granularity increase between Tier 1 approach 221 and Tier 2 approach 222, and then again between Tier 2 approach 222 and Tier 3 approach 223. Similarly, upwards arrow 332 indicates that reliance on judgement increases between Tier 3 approach 223 and Tier 2 approach 222, and then again between Tier 2 approach 222 and Tier 1 approach 221.

Continuing with FIG. 3, for Tier 1 approach 221, users 235a, e.g., policy analysts, may require data 224a, e.g., qualitative information regarding infrastructure health and/or system robustness, to focus on vulnerable components of infrastructure by performing, e.g., stress testing for risk 225a and/or resilience 226a, and produce outputs 227a, e.g., pathways to success for improving infrastructure against identified system disruptors. Goals of Tier 1 approach 221 may include, e.g., screening-level assessments, while visualization may be accomplished via, e.g., resilience indices and/or infrastructure scorecards. Finally, a Tier 1 approach 221 methodology may include “what if” scenarios and/or metrics.

Further with respect to FIG. 3, for Tier 2 approach 222, users 235b, e.g., risk and/or decision analysts, may require data 224b, e.g., domain variables of interest and/or connections among system domains, to focus on a detailed assessment per domain (such as physical, cyber, and/or social, etc.) of systematic disruptions by performing, e.g., stress testing for risk 225b and/or resilience 226b, and produce outputs 227b, e.g., robust system-wide resilience plans. Goals of Tier 2 approach 222 may include, e.g., semi-quantitative evaluations, while visualization may be accomplished via, e.g., risk/resilience matrices, interdependencies, and/or utility/decision analyses. Finally, examples of a Tier 2 approach 222 may include assessing food availability given supply chain, energy, and/or cyber network in response to cross-network disruptions.

Again with respect to FIG. 3, for Tier 3 approach 223, users 235c, e.g., network specialists, may require data 224c, e.g., detailed information on system structure as well as connections and/or properties of components, to focus on a detailed analyses of cascading impacts of threats across system components by performing, e.g., stress testing for risk 225c and/or resilience 226c, and produce outputs 227c, e.g., specialized changes and interventions to the infrastructure system and its components. Goals of Tier 3 approach 223 may include, e.g., targeting management alternatives at a system level, while visualization may be accomplished via, e.g., network science. Finally, examples of a Tier 3 approach 223 may include explicitly connecting cyber and/or physical infrastructure models to assess how specific disruptions result in economic impact of different policy interventions.

The tiered approach to stress testing critical infrastructure is part of UNDRR's Principles for Resilient Infrastructure as a key action of the principle for continuously learning. To cope with potential hazards, it is important to develop strategies to continually assess resilience and expose system weaknesses through collaboration with relevant stakeholders and the public. The Principles for Resilient Infrastructure have been developed to provide guidelines to create national scale net resilience gain and improve the continuity of critical services. Net resilience gain is an innovative concept and important pillar in achieving “net-zero,” requiring that all interventions into infrastructure must demonstrate that they enhance the systemic resilience of infrastructure and not contribute to any damage.

### Tier 1—Screening-Level Assessment

As the first stress test performance of a system, Tier 1 approach 221 (FIG. 2) maps the system's critical functions and interdependencies, via, e.g., stress testing risk 225a and/or resilience 226a (FIG. 2). Goals of Tier 1 approach 221 include answering questions such as the following: How does the system function? How are energy sources acquired and utilized to operate infrastructure? What are the social or operational considerations for safe infrastructure operation? And, for the infrastructure's physical assets, what are the various discrete yet interconnected parts? From these and other qualitative inquiries, analysts, e.g., users 235a (FIG. 2), chart the critical functions of the given infrastructure system-those components that are essential to system operation, and by which disruption would render the most severe, longest lasting, and systemic harms.

The methods of attaining a system's critical functions and interdependencies in Tier 1 approach 221 are qualitative and semi-qualitative. The toolbox for Tier 1 approach 221 may include existing data, e.g., inputs 224a (FIG. 2), tabletop exercises, or simple data analytics focused on identifying whether and where a problem exists. Process diagrams or flowcharts can be useful components of Tier 1 approach 221, visualizing directed policy intervention to either deflect the harm of a disruption or strengthen the system's ability to recover. This type of methodology is already used by the Cybersecurity and Infrastructure Security Agency's (CISA) to assess cyber resilience for infrastructure systems. CISA's methodology relies on interviews, plan reviews, and structured surveys to gather information about critical infrastructure to recommend areas for improvement.

The outcomes of a Tier 1 assessment 221 point to a broad understanding of the system, and the definition of common points of failure that could compromise operational capacity. An example of a Tier 1 assessment is the American Society of Civil Engineers' Infrastructure Report Card, which uses expert-level judgement and data, and subjectively scores the nation's infrastructure. With this output, policymakers and subject-matter experts (SMEs) can combine forces to explain where improvements, e.g., outputs 227a (FIG. 2), are needed at the subsystem level.

The intended users, creators, and owners of a Tier 1 analysis 221 are SMEs and regional policymakers, e.g., users 235a. Tier 1 approach 221 is intended for subjectivity in its analysis; employing users that are well-versed in a country or region's critical infrastructure systems and its vulnerabilities benefits the reliability of the assessment. Furthermore, this entry-level tier 221 is meant to be attainable at low resource expenditure, providing stakeholders with a screening-level assessment of the broad system of critical infrastructure.

### Tier 2—Semi-Quantitative Modeling

The goal of a Tier 2 analysis 222 (FIG. 2) is to identify interdependencies in a system to assess how the system's risk of cascading failures and resilience is affected at different stress levels. Interdependencies can be assessed across critical functions, as well as system domains, via, e.g., stress testing risk 225b and/or resilience 226b (FIG. 2). In-depth flowcharts and models may be useful aids in mapping the complexity of the system to explain the system, its subsystems, its critical functions, its risks, and its interdependencies.

To attain this goal, semi-quantitative methods may be employed for stress testing risk 225b and/or resilience 226b. Notably, metrics-based approaches in Tier 2 analysis 222 may include, among other examples, matrices of resilience performance that utilize data from Tier 1 approaches but disaggregate them into subdomains and time stages such as the Functional Resonance Analysis Method (FRAM) or the Resilience Matrix. Decision analysis methods, such as multi-criteria decision analysis and other structured decision approaches, provide an appropriate set of tools to evaluate scenarios, allowing an understanding of how change leads to gains or losses in the system and the impact (or lack thereof) from a particular investment. By applying stress testing through resilience analysis matrices, policymakers can witness where problems arise and when they arise based on the timing of a disruption.

The primary outcome of Tier 2 approach 222 is a semi-quantitative model that reveals how a system and its interrelated components respond to threats to improve the system's resilience. System-wide resilience strategies, e.g., outputs 227b (FIG. 2), can be created to resolve disharmony among multiple critical functions. Policymakers can use these resilience strategies as part of master plans that risk-based analysis alone cannot produce.

The intended users, creators, and owners of a Tier 2 analysis 222 are risk/decision analysts and national policymakers, e.g., users 235b (FIG. 2). Consultants for risk and decision analysis may be included beyond SMEs at the government level for more rigor in quantitative analysis. These consultants are meant to simplify the findings of a Tier 2 analysis 222 in a tangible report for national policymakers to construct a priority list for their resilience strategy. While Tier 2 approach 222 requires more resources, it moves beyond a Tier 1 assessment 221 to highlight how cascading interdependencies impact the system.

### Tier 3—Advanced Modeling

Tier 3 approach 223 includes, e.g., performing advanced modeling to assess infrastructure networks against random and/or targeted perturbation, such as via stress testing risk 225c and/or resilience 226c (FIG. 2). Goals of a Tier 3 assessment 223 include revealing an impact of any disruption to critical functions to a level that effective risk and resilience management plans can be developed. This process, e.g., stress testing risk 225c and/or resilience 226c, also includes, for instance, modeling a post-disruption recovery process to identify intervention opportunities that reduce downtime and the potential for spillover impacts to other sections, among other examples. As part of stress testing risk 225c and/or resilience 226c, sensitivity analysis and/or scenario analysis, for example, can provide a range of potential performance results so that resilience interventions, e.g., outputs 227c (FIG. 2), that are robust to a range of possible futures can be developed.

The methods, e.g., method 100 (FIG. 1), of Tier 3 approach 223 include, for instance, building a detailed model of important functions and related subsystems where each process and each component of the system is parameterized, e.g., as part of stress testing risk 225c and/or resilience 226c. Techniques employed by stress testing risk 225c and/or resilience 226c may include, but are not limited to, system dynamics, graph theory, Bayesian networks, and agent-based models that allow scenario analysis, as well as Monte Carlo simulation to support sensitivity analysis, among other examples. Furthermore, network science, ML, and/or AI, for example, may also be used in stress testing risk 225c and/or resilience 226c to provide a robust understanding of a system at a node-and-link level. Outcomes of a Tier 3 analysis 223 may include a detailed list of necessary interventions, e.g., outputs 227c. These interventions exist at a system level (i.e., Tier 1 and Tier 2 outcomes 227a and 227b, respectively), as well as at a granular asset level. This considerable amount of feedback is a deliberate result of Tier 3 approach 223, because its owners, e.g., users 235c (FIG. 2), may require a deep understanding of system and process dynamics.

The creators and owners of a Tier 3 analysis may be network scientists and/or national policymakers, e.g., users 235c, who may have a substantial grasp of the system's dynamics.

### DISCUSSION

As policymakers consider extensive investments to help society “bounce forward” from COVID disruptions, stress testing is a benchmark that must be satisfied to ensure system improvements will be able to withstand and recover from future crises. Abrupt disruptions and chaotic transitions for critical infrastructure systems are both dangerous and societally unacceptable, and can quickly cascade into various other facets of life. Both COVID-19 as well as the economic fallout from the war in Ukraine demonstrate the importance of planning for disruption, as well as the need for expeditious recovery and adaptation when disaster strikes. Policymakers and infrastructure planners must consider how to best extend the useful lifespan and service delivery capabilities of both new and existing infrastructure against a wide universe of threats in a manner that minimizes loss before, during, and after an event strikes. The fundamental transformation in society requires extending and enhancing the role of stress testing and making it a universal requirement for infrastructure investment consideration worldwide.

Current approaches for stress testing are based on risk assessment that emphasizes analyzing gaps or weaknesses by which a specific threat may gain access to a given system vulnerability, and cause a degree of harms. For example, in the aftermath of the 2008 Financial Crisis, the financial sector adapted a risk-based stress testing approach to evaluate how the large, interconnected networks in finance would respond to range of potentially catastrophic economic conditions. The assessment of systemic performance under a variety of threat scenarios in risk stress testing resulted in hardening financial system vulnerabilities.

However, a unified stress testing methodology has not been developed in the literature and the methodological approaches to stress testing are fragmented. The lack of methodological data for stress testing infrastructure makes it difficult for engineers and policymakers to evaluate proposed and existing assets. This is exacerbated by a paucity of information regarding how changes in local socioeconomic and environmental conditions contribute to a shift in infrastructure utility and performance under stress.

A streamlined stress testing method and system is needed to plan for and overcome uncertainty to infrastructure systems. The method and system of the present disclosure include a focus on mitigating future crises, taking into consideration an increased occurrence of complex scenarios where hazards can combine within interconnected networks, causing cascading effects to infrastructure systems. With cascading disruption in mind, the method and system of the present disclosure also incorporate elements of resilience at the forefront through, e.g., characterizing an infrastructure system's ability to prepare, absorb, recover, and adapt to adverse events. For example, a real-world system may first absorb the impact of an adverse event such a tsunami, after which the system recovers from the event in the short term, followed by a adaption to the event over the longer term. Including resilience as a central tenet for these infrastructure systems provides a “risk agnostic” point of view, taking into consideration any combination and duration of a hazard. As such, the method and system of the present disclosure include applications for, e.g., mitigating disruption to infrastructure systems, via stress testing, among other examples.

Methodologically, stress testing for critical infrastructure according to the method and system of the present disclosure, for instance, both accommodates a complex system's view and navigates uncertainties in data (e.g., limited characterization of infrastructural hazards, uncertain changes in socioeconomic habits post-shock that may alter the utility of infrastructure, etc.). Fundamentally, this is an acknowledgment of the unique characteristics, challenges, and needs of each individual case and infrastructure system. To accommodate such differences, the method and system of the present disclosure are both malleable and expansive, incorporating a mixture of quantitative and qualitative data. The outputs of the method and system of the present disclosure further comment upon, e.g., considerations of risk (evaluating potential magnitude of loss, given the introduction of one or more stressors) and resilience (evaluating the capacity for infrastructural system recovery and adaptation in the aftermath of perturbation).

The method and system of the present disclosure accommodate three core challenges beyond cost and time. Specifically, the method and system of the present disclosure: (a) delineate infrastructure systems that are placed at greater risk of disruption from a potential hazard, (b) incorporate a systems view of critical infrastructure that evaluates the conditions when infrastructural collapse (and a subsequent inability for recovery) becomes likely, and (c) accommodate varying availability of risk-based data, including, for example, material properties, use rates, future environmental and atmospheric conditions, management and data integration/analysis capabilities, and others.

A tiered approach to infrastructural testing is outlined in this document that accommodates, e.g., both an evaluation of complex systems, as well as a scalable methodology based upon the availability of data and/or the institutional resources available to conduct a basic or advanced assessment. The approach mimics conventional risk assessment practices—characterizing and evaluating risk at differing levels of scrutiny and granularity. In turn, this document adds an additional component—the tiering of infrastructural resilience analysis—to frame an infrastructure system's capacity to recover from and adapt to perturbation. Collectively, the risk and resilience-driven analysis informs infrastructural stress testing.

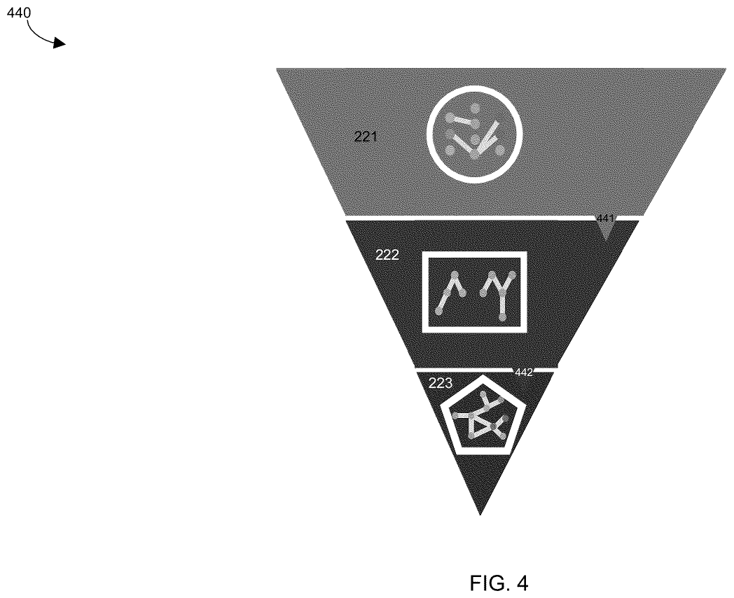

FIG. 4 is a diagram 440 illustrating methodologies for the three-tiered approach of FIG. 2, according to an embodiment. As shown in FIG. 4, an analysis 221 at Tier 1 may feed into and/or inform 441 a further analysis 222 (FIG. 2) at Tier 2. In turn, an analysis 222 at Tier 2 may feed into and/or inform 442 a further analysis 223 (FIG. 2) at Tier 3. In an embodiment, a Tier 1 methodology 221 may include, e.g., prioritizing critical functions, and may be based on, e.g., expert opinion and/or decision science, with goals including, e.g., identifying and/or prioritizing critical functions. According to another embodiment, a Tier 2 methodology 222 may include, e.g., refining the Tier 1 prioritization 221 of critical functions and/or identifying key performance indictors (KPIs), with goals including, e.g., identifying measurable metrics for critical functions. In one such embodiment, the Tier 2 methodology 222 may be based on, e.g., expert opinion and/or decision science, and may include, e.g., adjust prioritizations based on cascading effects. Further, in yet another embodiment, a Tier 3 methodology 223 may include performing, e.g., an asset-level evaluation of a real-world system, with goals including, e.g., identifying single points of failure and/or comparing potential changes at a system level. In one such embodiment, the Tier 3 methodology 223 may employ, e.g., a data-driven approach, using techniques such as digital twins, ML/AI, and/or network science, among other examples, to model and/or simulate a real-world system and its functions, services, and/or assets.

Table 1 shows a matrix of exemplary KPIs according to an embodiment. In an embodiment, KPIs, such as those shown in the matrix of Table 1, may be used to highlight a real-world system's resilience as a function of space (e.g., a physical, cyber, and/or social space) and/or time (e.g., during an absorption, recovery, and/or adaptation phase). According to one such embodiment, a KPI may be scored based on an expected outcome from top risks.

TABLE 1
Key performance indicators

| | Absorb | Recover | Adapt |
|---|---|---|---|
| Physical | Identifies: physical | Identifies: physical | Identifies: physical |
| | infrastructure's ability | infrastructure's ability to | infrastructure's ability to modify |
| | to withstand disruption | overcome initial disruption | from long-term disruption |
| Cyber | Identifies: cyber | Identifies: cyber systems' | Identifies: cyber systems' ability |
| | systems' ability to | ability to overcome initial | to modify from long-term |
| | withstand disruption | disruption | disruption |
| Social | Identifies: community's | Identifies: community's | Identifies: community's ability |
| | ability to withstand | ability to overcome initial | to modify from long-term |
| | disruption | disruption | disruption |

The process of creating KPIs in Table 1 to represent a real-world system's resilience may entail the following: identify a critical success factor based on the space-time relationship (e.g., Physical-Absorb, Cyber-Absorb, Social-Absorb, etc.), identify a unit of time that suits the time-stage of the KPI (absorb, recover, or adapt), and indicate good and bad performance.

A critical success factor is the main substance of a KPI that is being evaluated. It is mission-critical, testable, and can be measured by quantitative and/or qualitative metrics. To deem if a critical success factor is mission-critical, developers of a KPI should be able to answer “yes” to the following consideration: “If this critical success factor for my system is not performing well, will my system be notably disrupted by financial, operational, competitive, production, or other important means?”

Identifying a unit of time that suits the time-stage of the KPI is performed by considering a disruption to the space-time relationship: “absorb” encompasses a timeframe just before a disruption, “recover” is the timeframe of the immediate aftermath, and “adapt” is the long-term timeframe after a disruption occurs.

Indicating good and bad performance for a KPI is specific to a system, whereas one application's measures of good and bad performance may not be indicative for another application. Historical evaluation of the critical success factor should be monitored to identify average performance, good performance, and bad performance as deemed by the system's key personnel.

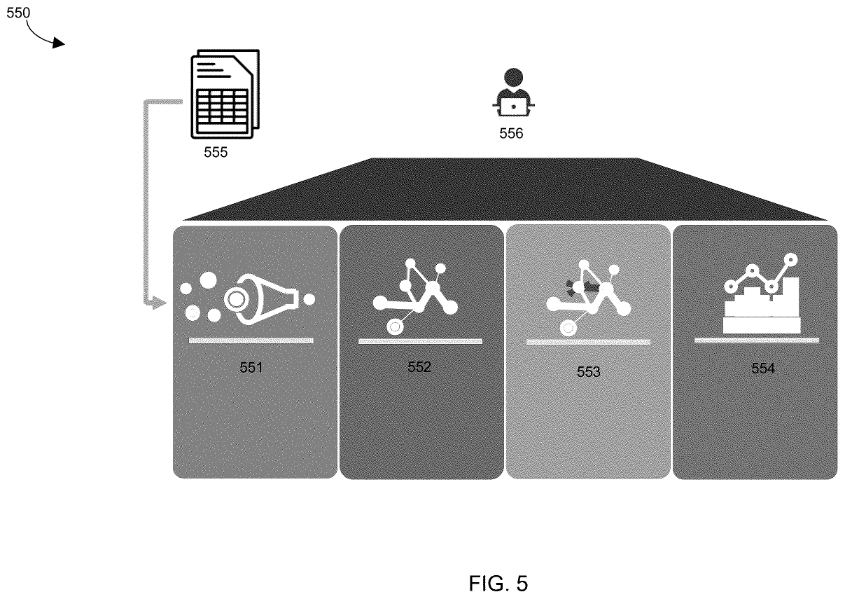

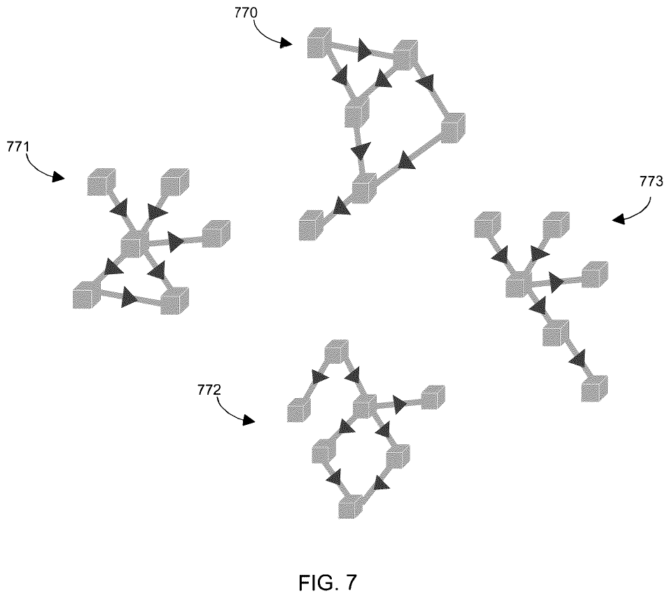

FIG. 5 is an overview of a framework 550 for Tier 3 asset-level resilience analysis, e.g., using a Tier 3 methodology 223 (FIG. 2), according to an embodiment. As shown in FIG. 5, framework 550 includes four components—onboarding 551, modeling 552, planning 553, and visualization 554—as well as graphical user interface (GUI) 556. In an embodiment, the onboarding 551 component may include, e.g., data onboarding, by performing data acquisition operations such as automated ETL (extract, transform, load) and/or metadata capture, among other examples. Further, in one such embodiment, onboarding 551 component may acquire data such as enterprise data 555. According to another embodiment, modeling 552 component may be an automated component, and may perform operations such as mapping and/or identifying data gaps, among other examples. Further, in one such embodiment, modeling 552 component may interface or connect with external data sources, for example to perform automatic discovery of external drivers as described in more detail hereinbelow with respect to FIG. 7. According to yet another embodiment, like modeling 552 component, planning 553 component may also be an automated component. In one such embodiment, planning 553 component may perform operations such as identifying highest impact opportunities, recommending resilience strategies, and/or quantifying resilience, among other examples. According to an embodiment, visualization 554 component may include functionality such as visualizing results, e.g., from planning 553 component, and/or viewing all data together in an integrated or coherent fashion. Further, in one such embodiment, visualization 554 component may support fast and/or iterative queries and may be code-free or accessible via an application programming interface (API). In another embodiment, GUI 556 may enable a user to interact with and/or control components 551, 552, 553, and/or 554, as well as to view data visualizations and other displays or outputs provided by component 554. In an embodiment, method 100 (FIG. 1) may be used to implement framework 550 including components 551, 552, 553, and/or 554, as well as GUI 556.

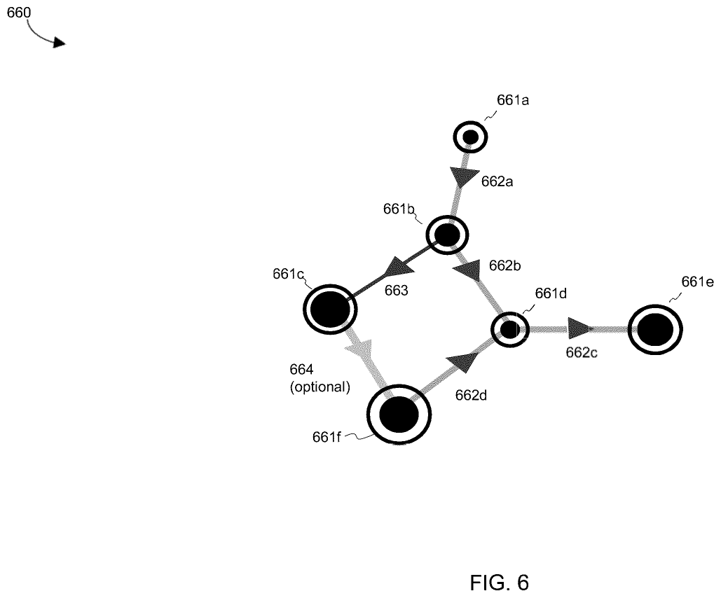

FIG. 6 is an example of relationships in a network 660 according to an embodiment. As shown in FIG. 6, network 660 includes nodes 661a-f and edges 662a-d, 663, and 664. In some embodiments, network 660 may be automatically created as part of a Tier 3 analysis 223 (FIG. 2) by modeling 552 component using data obtained by onboarding 551 component (FIG. 5). According to an embodiment, each of edges 662a-d may represent a relationship between nodes that is understood. Thus, in one such embodiment, edge 662a may indicate an understood relationship between nodes 661a and 661b; edge 662b may indicate an understood relationship between nodes 661b and 661d; edge 662c may indicate an understood relationship between nodes 661d and 661c; and edge 662d may indicate an understood relationship between nodes 661f and 661d. According to another embodiment, edge 663 may represent a relationship between nodes that is incomplete, e.g., that is incompletely understood, characterized, and/or described. Thus, in one such embodiment, edge 663 may indicate an incomplete relationship between nodes 661b and 661c. In some embodiments, designating relationships as incomplete may enable identifying and/or reporting data gaps, such as data gap identification performed by modeling 552 component, among other examples. Further, in yet another embodiment, edge 664 may represent a relationship between nodes that is added or included by an expert, e.g., a user 235c (FIG. 2), such as a SME. Thus, in one such embodiment, edge 664 may indicate an expert-designated relationship between nodes 661c and 661f. According to an embodiment, a process of adding user-specified relationships such as 664 may be informed by a Tier 1 analysis 221 and/or a Tier 2 analysis 222 (FIG. 2). In some embodiments, when edges representing understood relationships, incomplete relationships, and user-added relationships are displayed or visualized, each type of edge may be, e.g., colored, shaded, and/or illustrated differently.

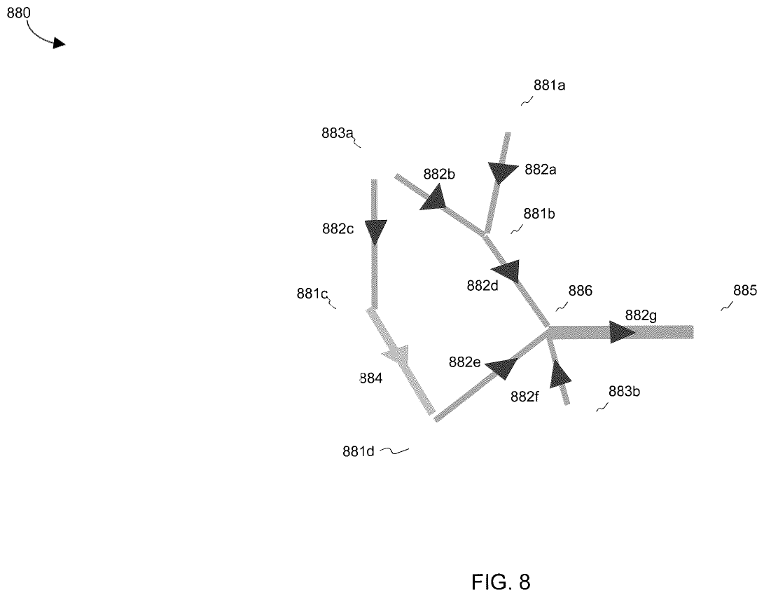

FIG. 7 depicts examples 770-773 of third-party/external data regarding network relationships—such as causal relationships, among other examples—according to an embodiment. In some embodiments, third-party/external data, e.g., exemplary network data 770-773, may be searched or mined as part of a Tier 3 analysis 223 (FIG. 2) by modeling 552 component (FIG. 5) to automatically discover external drivers. Further, in other embodiments, an existing network, e.g., network 660 (FIG. 6), may be supplemented or augmented with such automatically discovered external drivers that have causal relationships to node(s) of the existing network, as described in more detail hereinbelow with respect to FIG. 8. According to an embodiment, network data 770 may include data regarding, e.g., economic/econometrics-based network relationships. In one such embodiment, network data 770 may be obtained from a third-party or external source such as the U.S. Bureau of Labor Statistics (BLS), among other examples. According to another embodiment, network data 771 may include data regarding network relationships in areas such as weather/climate, freight/supply chain/distribution, and/or mobility/transit, among other examples. In one such embodiment, network data 771 may be obtained from a third-party or external source, e.g., Replica, Inc. (Leawood, KS), for mobility/transit data. Further, in yet another embodiment, network data 772 may include data regarding, e.g., computing/digital/cyber-based network relationships. In an embodiment, network data 773 may include data regarding network relationships in areas such as power/energy, rail, coal, wind, and/or solar, among other examples. Further, in certain embodiments, third-party/external network data such as data 770-773 may be stored in a repository or database that is supplemented or expanded over time with new or additional network relationship data.

FIG. 8 illustrates stress testing and resilience planning for an example network 880, according to an embodiment. As shown in FIG. 8, network 880 includes nodes 881a-d, 885, and 886, external drivers 883a-b, and edges 882a-g and 884. In an embodiment, understood relationships may be indicated by edges 882a (nodes 881a and 881b), 882b (driver 883a and node 881b), 882c (driver 883a and node 881c), 882d (nodes 881b and 886), 882e (nodes 881d and 886), 882f (driver 883b and node 886), and 882g (nodes 886 and 885), while an expert-added relationship may be indicated by edge 884 (nodes 881c and 881d). According to some embodiments, network 880 may be employed as part of a Tier 3 analysis 223 (FIG. 2) by planning 553 component (FIG. 5) to, e.g., identify highest impact investment opportunities, recommend/enable resilience strategies or testing of mitigation methods (such as redundancy, selective redundancy, etc.), and/or quantify resilience, among other examples. In other embodiments, planning 553 component may stress test network 880 by employing techniques such as network science, ML, and/or AI models/methods, among other examples.

Continuing with FIG. 8, according to an embodiment, network 880 may result from supplementing or modifying an existing network, e.g., network 660 (FIG. 6), with network relationship data from automatically discovered external drivers, such as in the manner described hereinabove with respect to FIG. 7. For example, in one such embodiment, incomplete relationship 663 between nodes 661b and 661c (FIG. 6) in network 660 may be resolved or augmented via the automatic discovery process, and the results reflected in network 880 by external driver 883a with understood relationships 882b and 882c to nodes 881b and 881c, respectively. According to an embodiment, driver 883a and/or edges 882b-c may represent an economic/econometrics-based network relationship mined from or discovered in, e.g., network data 770 (FIG. 7). Similarly, in another embodiment, driver 883b with edge 882f to node 886 in network 880 may reflect a result of augmenting or supplementing network 660 with a computing/digital/cyber-based network relationship mined from or discovered in, e.g., network data 772 (FIG. 7).

Again with respect to FIG. 8, certain embodiments may optionally utilize Tier 1 methodology 221 and/or Tier 2 methodology 222 (FIG. 2) to, e.g., isolate critical assets or components and, as a further option, identify points of failure upstream from such critical assets/components. In an embodiment, isolating critical assets/components may employ KPIs, such as the KPIs described hereinabove with respect to Table 1, among other examples. For instance, according to an embodiment, node 885 may represent a critical asset isolated via the application of methodology 221 and/or 222. Similarly, node 886 may represent a failure point identified upstream of node 885. In one such embodiment, when network 880 is displayed or visualized, node 885 may be, e.g., colored, shaded, and/or illustrated differently from nodes 881a-d and 886 to indicate that node 885 represents a critical asset. Likewise, node 886 may be, e.g., colored, shaded, and/or illustrated differently from nodes 881a-d and 885 to indicate that node 886 represents a failure point.

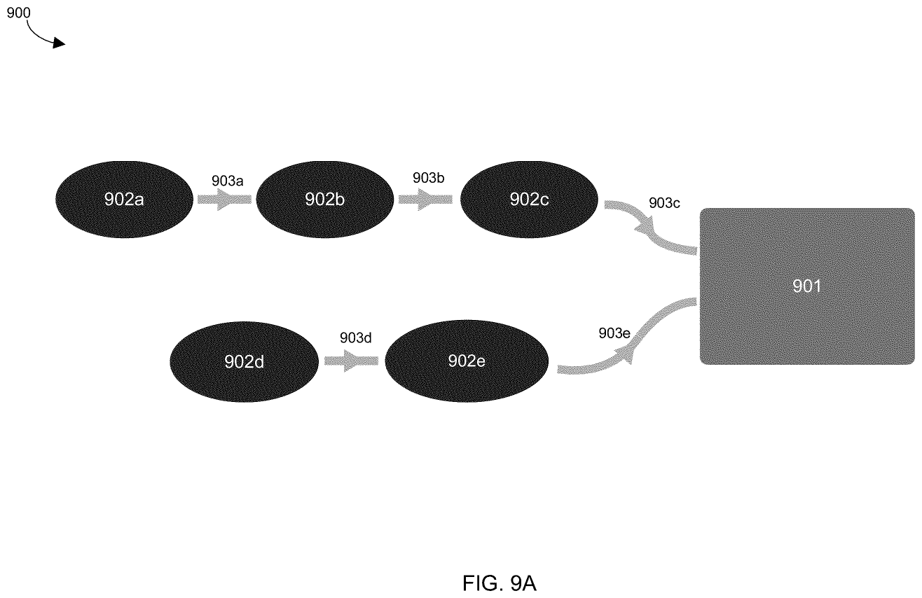

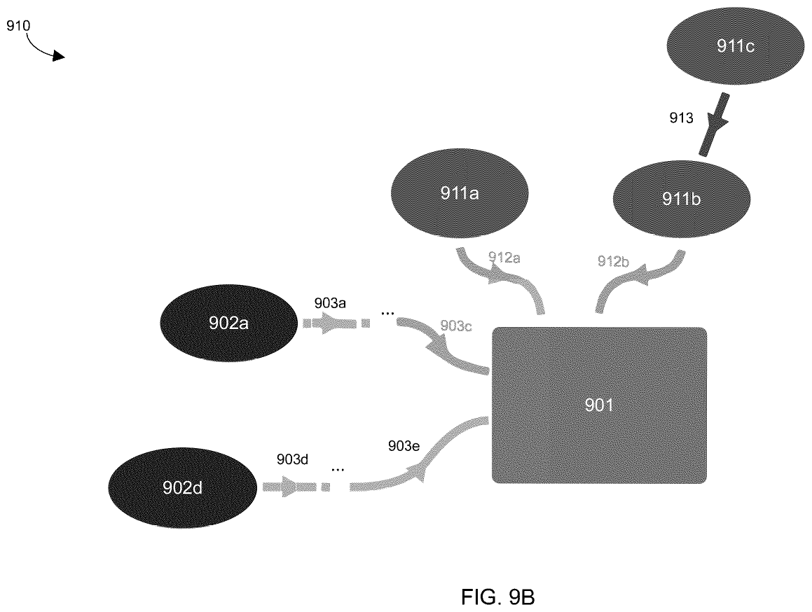

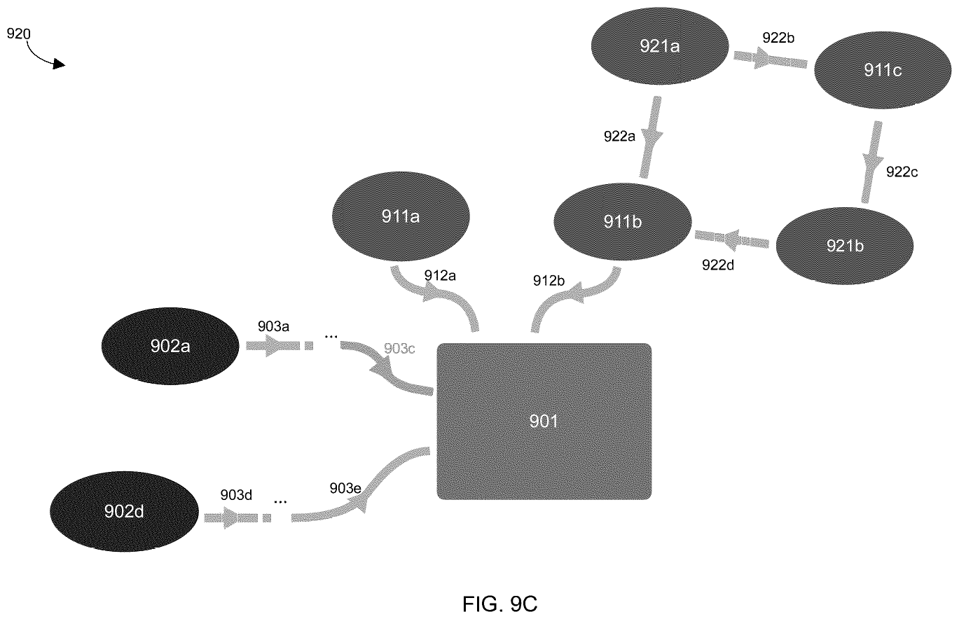

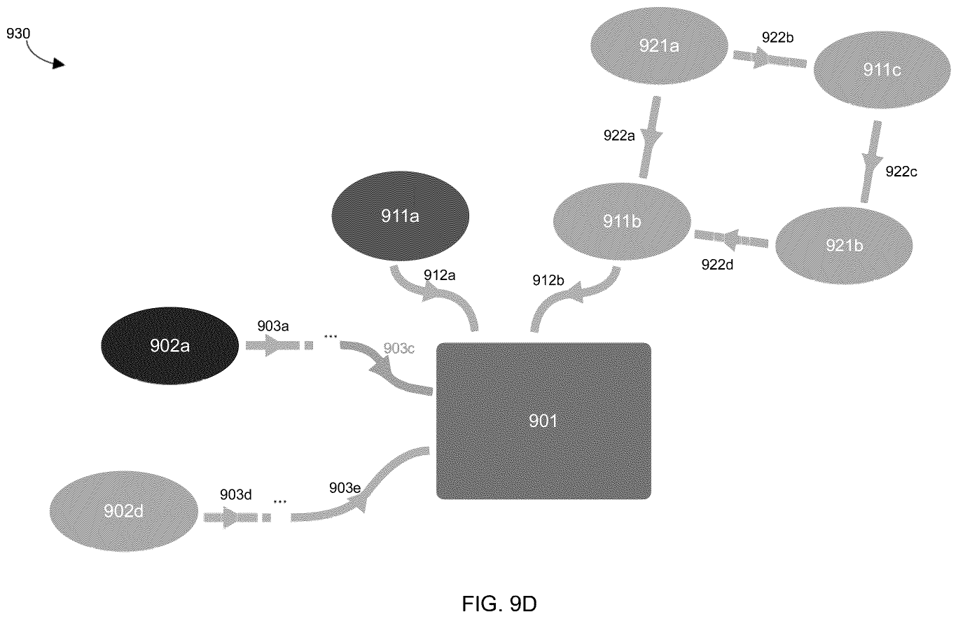

FIG. 9A illustrates an example 900 of a loan portfolio risk analysis, according to an embodiment. As shown in FIG. 9A, example 900 includes loan portfolio segment 901, factors 902a-c (linked to each other and segment 901 via edges 903a-c), and factors 902d-e (linked to each other and segment 901 via edges 903d-e). In example 900, segment 901 may be a loan portfolio segment for wind electrical generation, and the analysis of example 900 may consist of evaluating the risk of a 9%/year loan. The linked factors 902a, 902b, and 902c may be, respectively, global warming, public sentiment (i.e., towards global warming 902a), and public policy (i.e., with respect to global warming 902a, and resulting from public sentiment 902b); likewise, the linked factors 902d and 902e may be, respectively, global oil prices and costs of competing electrical sources (i.e., as a function of prices 902d). Current approaches to portfolio risk analysis are based on, e.g., a fixed exposure rate and a roll up across all loans to arrive at a yearly risk. With existing methods, stress testing typically consists of estimating exposure to adverse high-level events. Similarly, using current techniques, determining resilience at this level in the case of example 900 consists of addressing sources of risk, such as factors 902a-c, by balancing the portfolio (which includes segment 901) with financial assets that are positively impacted by low oil prices (i.e., for risk sources 902d-e) and public indifference to global warming (i.e., for risk sources 902a-c).

FIG. 9B illustrates an example 910 of modeling a network, according to an embodiment. As shown in FIG. 9B, example 910 includes the elements of example 900 (such as factors 902a and 902d, and edges 903a, 903c, 903d, and 903c). However, in an embodiment, the network shown in FIG. 9B may also include nodes 911a-c and edges 912a-b and 913 that are, e.g., automatically added as part of a Tier 3 analysis 223 (FIG. 2) by modeling 552 component using data obtained by onboarding 551 component (FIG. 5). According to one such embodiment, nodes 911a, 911b, and 911c added via Tier 3 analysis 223 correspond to electrical relays/controllers, aluminum prices, and coal prices, respectively; similarly, edges 912a-b indicate understood relationships between nodes 911a-b, respectively, and segment 901, while edge 913 indicates an incomplete relationship between nodes 911c and 911b, e.g., that a relationship between coal and aluminum prices is not fully understood/characterized.

FIG. 9C illustrates an example 920 of automatic discovery of external drivers, according to an embodiment. As shown in FIG. 9B, example 920 includes the elements of example 900 (such as factors 902a and 902d, and edges 903a, 903c, 903d, and 903c). Further, example 920 includes nodes 911a-c, as well as edges 912a-b, that were added via the network modeling process described in more detail hereinabove with respect to FIG. 9B. In an embodiment, example 920 of FIG. 9C may also include nodes 921a-b as well as edges 922a-d. According to one such embodiment, nodes 921a-b and edges 922a-d may be added to the network of example 920 by, e.g., a process of automatically discovering external drivers as part of a Tier 3 analysis 223 (FIG. 2) by modeling 552 component (FIG. 5). For example, in an embodiment, added node 921a may represent an external driver based on freight via rail, while added node 921b may represent an external driver based on electricity generation via coal. Likewise, in another embodiment, edge 913 of FIG. 9B indicating an incomplete relationship between coal 911c and aluminum 911b prices is replaced by newly-added edges 922a-d of FIG. 9C. According to one such embodiment, edges 922a-b indicate that understood relationships exist between rail-based freight 921a and nodes 911b-c, respectively. Similarly, in yet another embodiment, edges 922c-d indicate that understood relationships exist between coal prices 911c, coal-based electricity generation 921b, and aluminum prices 911b. According to an embodiment, drivers 921a-b and edges 922a-d of FIG. 9C may be identified by searching or mining, e.g., network data 773 (FIG. 7) including data about network relationships in areas such as power/energy, rail, coal, wind, and/or solar, among other examples.

FIG. 9D illustrates an example 930 of stress testing and resilience planning, according to an embodiment. In an embodiment, the stress testing and resilience planning of example 930 may be performed by planning 553 component (FIG. 5) as part of a Tier 3 analysis 223 (FIG. 2) to, e.g., identify highest impact investment opportunities, recommend/enable resilience strategies or testing of mitigation methods (such as redundancy, selective redundancy, etc.), and/or quantify resilience, among other examples. According to one such embodiment, planning 553 component may stress test the network of example 930 by employing techniques such as network science, ML, and/or AI models/methods, among other examples. In another embodiment, as shown in FIG. 9D, stress testing and resilience planning in example 930 performed by planning 553 component may identify factors 911a (relays and controllers) and 902a (global warming) as having a highest impact on loan portfolio segment 901. According to one such embodiment, all other nodes, which are not identified as highest impact, e.g., nodes 902d, 911b-c, and 921a-b may be, e.g., colored, shaded, and/or illustrated differently from nodes 902a and 911a. It should be noted that factors and/or relationships are identified automatically in the embodiment illustrated by FIG. 9D, i.e., without human involvement or participation.

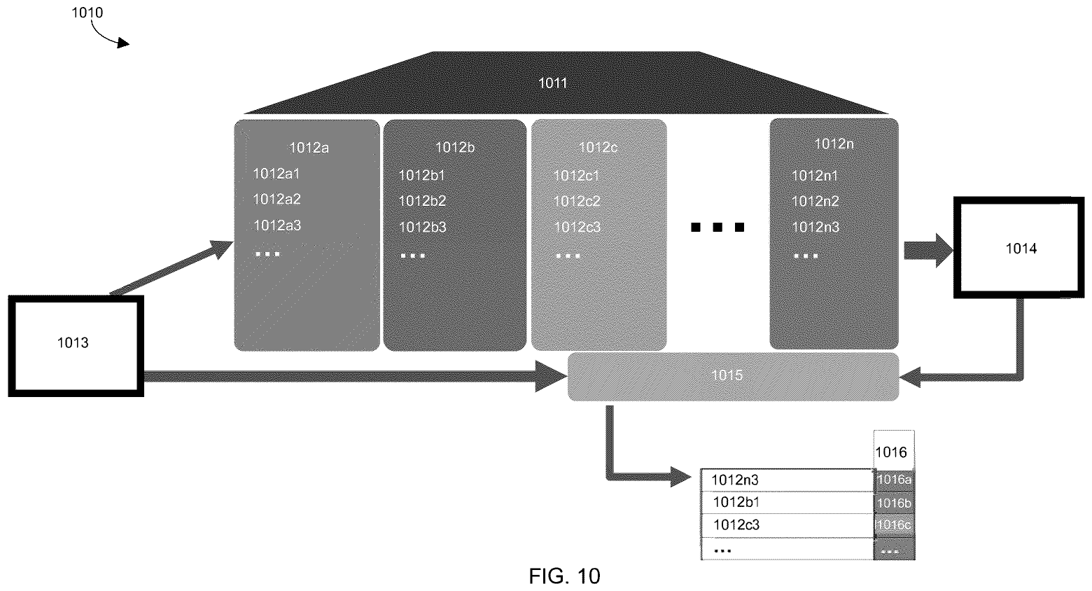

FIG. 10 is an overview 1010 of determining critical functions of a system, according to an embodiment. In an embodiment, a process determining critical functions may be performed as part of Tier 1 methodology 221 (FIG. 2). As shown in FIG. 10, according to an embodiment, such a process may employ one or more libraries of critical functions, e.g., critical function library 1011. The library 1011 may be, e.g., a CISA National Critical Functions Set, or any other suitable repository or library of critical functions known to those of skill in the art. Continuing with FIG. 10, in an embodiment, library 1011 may include one or more categories 1012a, 1012b, 1012c, and 1012n. According to one such embodiment, categories 1012a, 1012b, 1012c, and 1012n may correspond to, e.g., connection/network-based critical functions, distribution-based critical functions, management-based critical functions, and supply-based critical functions, respectively. Other known critical function categories are also suitable. In another embodiment, each category 1012a, 1012b, 1012c, and 1012n may include one or more critical functions, e.g., critical functions 1012a1-3, 1012b1-3, 1012c1-3, and 1012n1-3, respectively. According to one such embodiment, critical functions 1012a1, 1012a2, and 1012a3 in, e.g., a connection/network-based category, may be, for instance, operating a core network, providing cable access network services, and providing internet-based content/information/communication services, respectively; critical functions 1012b1, 1012b2, and 1012b3 in, e.g., a distribution-based category, may be, for instance, distributing electricity, maintaining supply chains, and transmitting electricity, respectively; critical functions 1012c1, 1012c2, and 1012c3 in, e.g., a management-based category, may be, for instance, conducting elections, developing/maintaining public works/services, and managing hazardous materials, respectively; and critical functions 1012n1, 1012n2, and 1012n3 in, e.g., a supply-based category, may be, for instance, exploration/extraction of fuels, fuel refining/processing, and generating electricity, respectively.

Again with reference to FIG. 10, in an embodiment, library 1011 may be developed based at least in part on input from an evaluation 1013 of risks and/or economic sectors relevant to the system, i.e., the system undergoing Tier 1 analysis 221. According to one such embodiment, evaluation 1013 may include assessing the risks and/or economic sectors according to scoring criteria. In another embodiment, scoring criteria for the risks may include threat, vulnerability, and consequence, among other examples; likewise, scoring criteria for the economic sectors may include jobs, income, and investments, among other examples. Further, in yet another embodiment, determining critical functions of the system may include selection 1014 of critical functions from library 1011 that are most relatable to the system. In turn, according to one such embodiment, the selected 1014 critical functions may be used as input, along with evaluation 1013, for performing scoring 1015, e.g., judgement scoring, between the relevant risks and/or economic sectors and the selected 1014 critical functions. Further, in yet another embodiment, scoring 1015 may employ, e.g., multiple-criteria decision analysis (MCDA), multiple-criteria decision-making (MCDM), or any other suitable technique known to those of skill in the art. According to an embodiment, scoring 1015 may generate one or more scores 1016 corresponding to one or more respective critical functions, e.g., scores 1016a, 1016b, and 1016c corresponding to respective critical functions 1012n3 (e.g., generating electricity), 1012b1 (e.g., distributing electricity), and 1012c3 (e.g., managing hazardous waste).

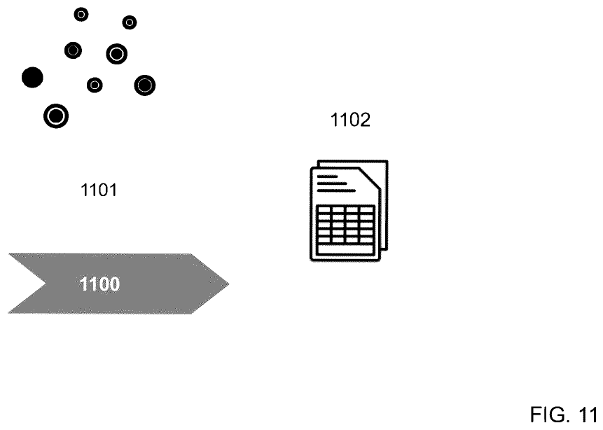

FIGS. 11-14, 15A-B, and 16A-B illustrate a step-based framework for Tier 3 asset-level assessment, e.g., Tier 3 approach 223 (FIG. 2), according to an embodiment. The framework illustrated in FIGS. 11-14, 15A-B, and 16A-B may be implemented by embodiments, e.g., method 100 (FIG. 1).

FIG. 11 illustrates a step 1100 of data integration, according to an embodiment. In an embodiment, step 1100 may include combining data into a single platform 1101. According to one such embodiment, data serving as input for platform 1101 may be sourced at least in part from, e.g., user-provided data 1102. In another embodiment, data integration step 1100 may be performed by, e.g., onboarding 551 component (FIG. 5).

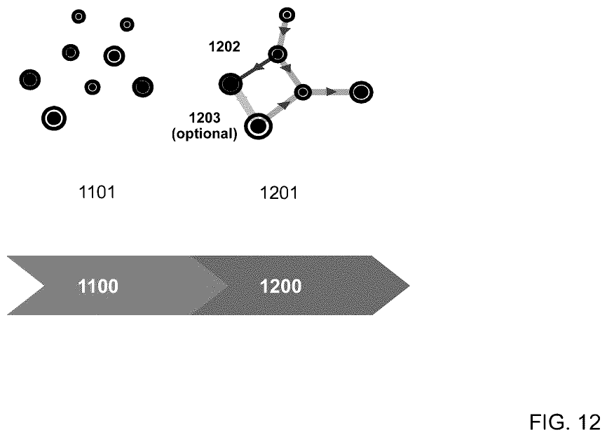

FIG. 12 illustrates a step 1200 of network modeling, according to an embodiment. In an embodiment, step 1200 may include identifying 1201 network causal relationships, such as confounded or incomplete relationships, e.g., relationship 1202 or 663 (FIG. 6). According to one such embodiment, as an optional part of identifying 1201 network causal relationships, user-specified relationships, e.g., relationship 1203 or 664 (FIG. 6), may also be added based on a result of undertaking a Tier 1 analysis 221 and/or a Tier 2 analysis 222 (FIG. 2). In another embodiment, network modeling step 1100 may be performed by, e.g., modeling 552 component (FIG. 5).

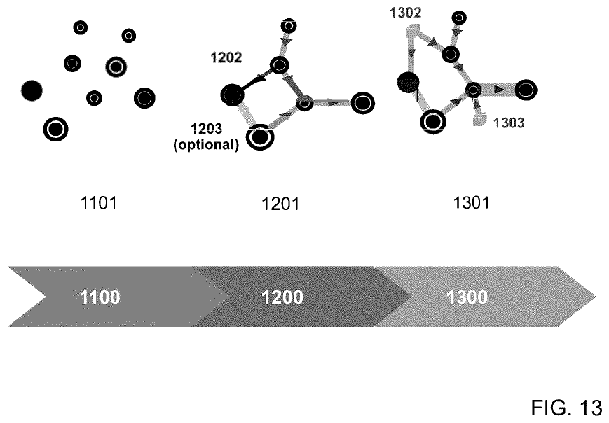

FIG. 13 illustrates a step 1300 of automatic discovery 1301 of external drivers, according to an embodiment. In an embodiment, automatic discovery 1301 of external drivers may be performed by, e.g., modeling 552 component (FIG. 5). According to one such embodiment, step 1300 may result in discovery of external drivers 1302 and 1303, which may be, e.g., an economic/econometrics-based driver mined or located from data 770 and a computing/digital/cyber-based driver mined or located from data 772 (FIG. 7), respectively. In another embodiment, drivers discovered during step 1300 and process 1301, e.g., 1302 and 1303, may be integrated with an existing network model that resulted from steps 1100 and 1200.

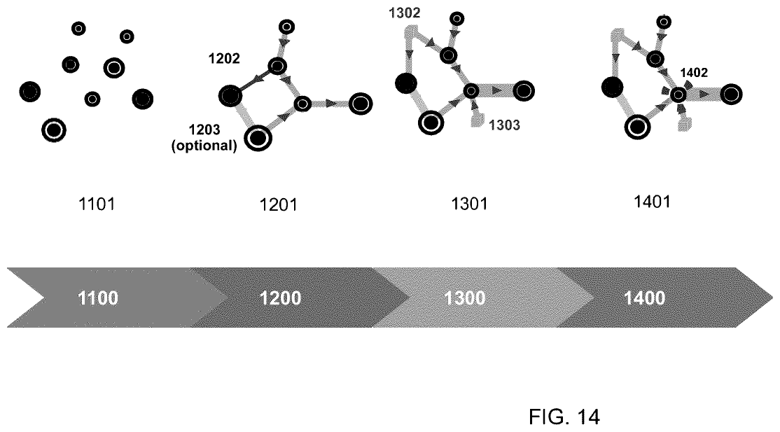

F FIG. 14 illustrates a step 1400 of stress testing, according to an embodiment. In an embodiment, step 1400 may include a process 1401 of stress testing a completed model, e.g., a model resulting from steps 1100, 1200, and/or 1300. According to one such embodiment, stress testing 1401 may be performed by, e.g., planning 553 component (FIG. 5), using techniques such as network science, ML, and/or AI models/methods, among other examples. In another embodiment, process 1401 may result in identifying a failure point, e.g., node 1402.

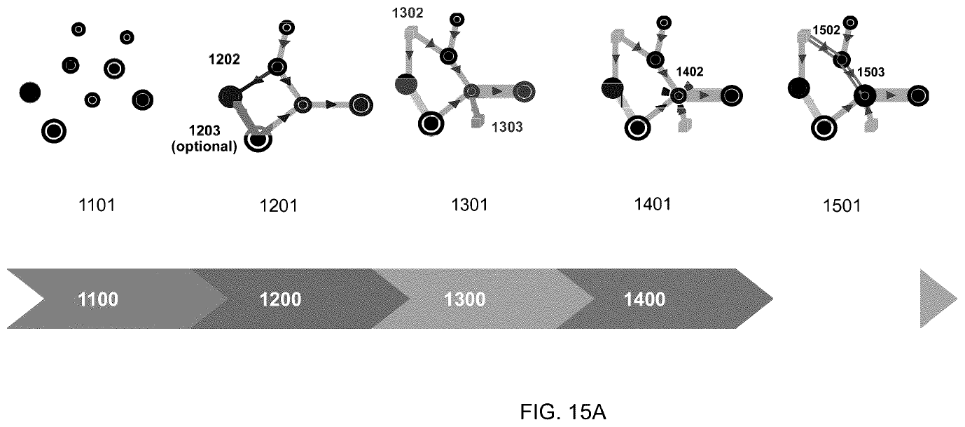

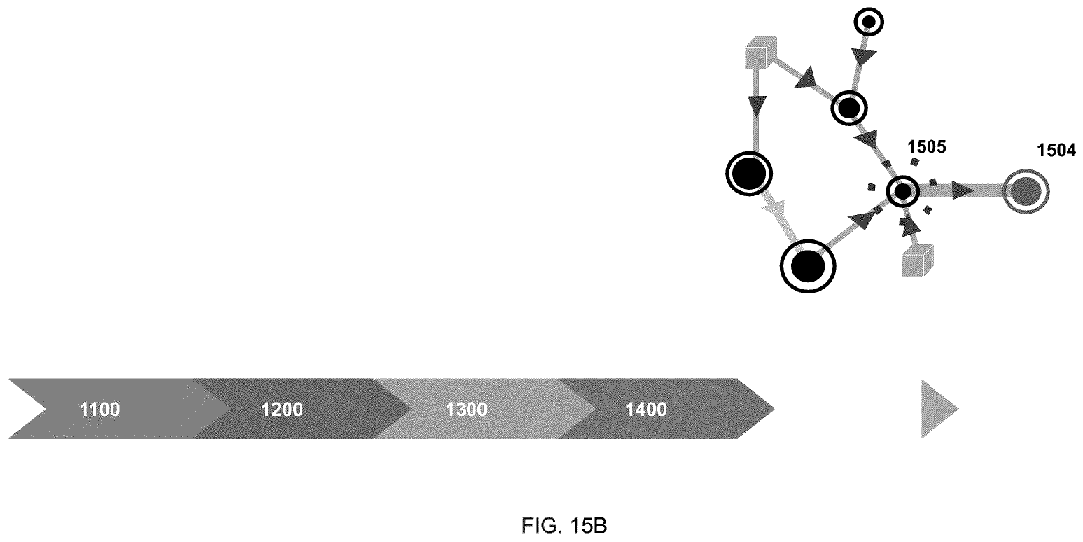

FIG. 15A illustrates a step 1500 of generating resilience strategies, according to an embodiment. In an embodiment, step 1500 may include a process 1501 of developing one or more resilience strategies for a completed model, e.g., a model resulting from steps 1100, 1200, and/or 1300, which process 1501 may also be informed by stress testing the model, e.g., at step 1400. According to one such embodiment, developing 1501 resilience strategies may be performed by, e.g., planning 553 component (FIG. 5). In another embodiment, process 1501 may result in identifying highest impact investment opportunities, recommending/enabling resilience strategies or testing of mitigation methods (such as redundancy, selective redundancy, etc.), and/or quantifying resilience, among other examples. For instance, according to one such embodiment, a result of step 1500 may be that the network is modified to include, e.g., reinforced or redundant links between nodes, such as links 1502 and 1503 shown in FIG. 15A.

FIG. 15B illustrates optional identification of critical assets as part of step 1500, according to an embodiment. In an embodiment, optional identification of critical assets in step 1500 may utilize, e.g., a Tier 1 methodology 221 and/or Tier 2 methodology 222 (FIG. 2) to isolate critical assets or components, such as critical asset 1504. According to one such embodiment, as further optional functionality at step 1500, failure points that are upstream from critical assets/components may also be identified, such as failure point 1505. In another embodiment, isolating critical assets/components may employ KPIs, such as the KPIs described hereinabove with respect to Table 1, among other examples.

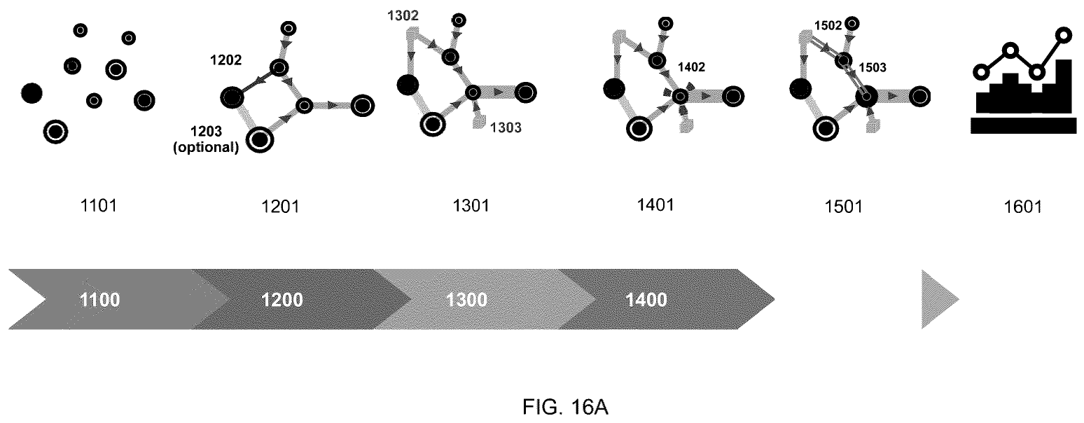

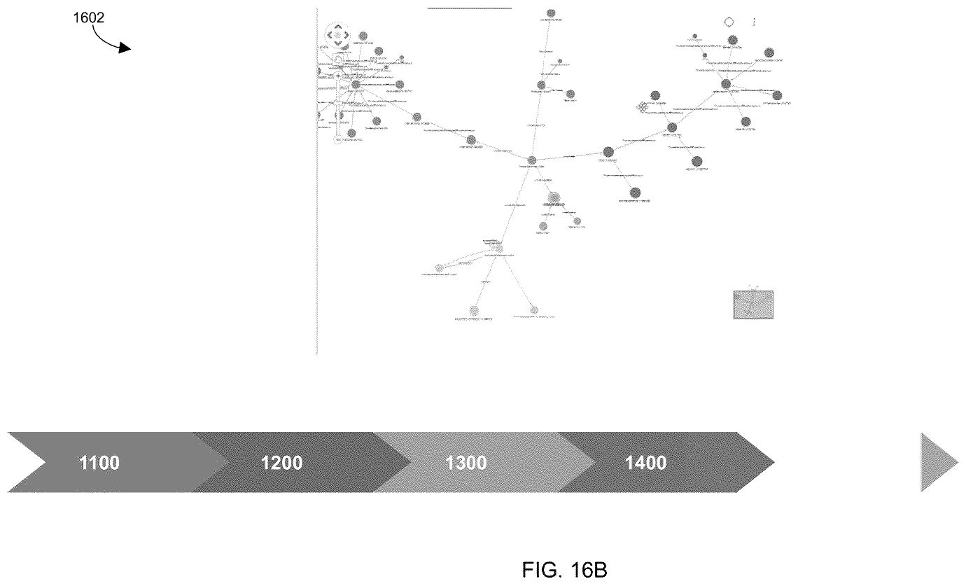

FIG. 16A illustrates a step 1600 of visualizing results, according to an embodiment. In an embodiment, step 1600 may include displaying or presenting 1601 results, e.g., of steps 1400 and/or 1500, in an easily interpretable interface. FIG. 16B depicts an example interface 1602 according to an embodiment. In an embodiment, interface 1602 may be a dashboard for presenting results in an easily understandable manner so as to provide a smooth user experience. According to another embodiment, displaying 1601 results at step 1600 may be performed by, e.g., visualization 554 component (FIG. 5), using an interface such as example interface 1602 or GUI 556 (FIG. 5). However, any suitable interface known in the art may be used.

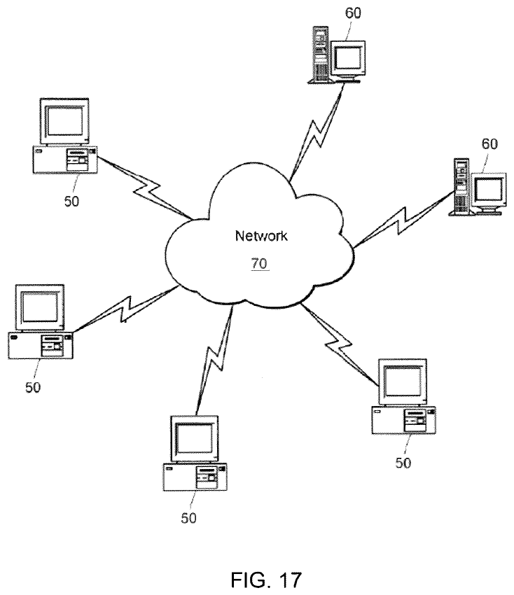

FIG. 17 is a schematic view of a computer network in which embodiments may be implemented. Client computer(s)/devices 50 and server computer(s) 60 provide processing, storage, and input/output (I/O) devices executing application programs and the like. Client computer(s)/device(s) 50 can also be linked through communications network 70 to other computing devices, including other client device(s)/processor(s) 50 and server computer(s) 60. Communications network 70 can be part of a remote access network, a global network (e.g., the Internet), cloud computing servers or service, a worldwide collection of computers, local area or wide area networks, and gateways that currently use respective protocols (TCP/IP (Transmission Control Protocol/Internet Protocol), Bluetooth®, etc.) to communicate with one another. Other electronic device/computer network architectures are suitable.

FIG. 18 is a block diagram illustrating an example embodiment of a computer node (e.g., client processor(s)/device(s) 50 or server computer(s) 60) in the computer network of FIG. 17. Each computer node 50, 60 contains system bus 79, where a bus is a set of hardware lines used for data transfer among components of a computer or processing system. Bus 79 is essentially a shared conduit that connects different elements of a computer system (e.g., processor, disk storage, memory, I/O ports, network ports, etc.) that enables transfer of information between the elements. Attached to system bus 79 is I/O device interface 82 for connecting various input and output devices (e.g., keyboard, mouse, display(s), printer(s), speaker(s), etc.) to the computer node 50, 60. Network interface 86 allows the computer node to connect to various other devices attached to a network (e.g., network 70 of FIG. 17). Memory 90 provides volatile storage for computer software instructions 92 and data 94 used to implement an embodiment of the present disclosure (e.g., the method 100 described hereinabove with respect to FIG. 1). Disk storage 95 provides non-volatile storage for computer software instructions 92 and data 94 used to implement an embodiment of the present disclosure. Central processor unit 84 is also attached to system bus 79 and provides for execution of computer instructions.

In one embodiment, the processor routines 92 and data 94 are a computer program product (generally referenced as 92), including a computer readable medium (e.g., a removable storage medium such as DVD-ROM(s), CD-ROM(s), diskette(s), tape(s), etc.) that provides at least a portion of the software instructions for the disclosure system. Computer program product 92 can be installed by any suitable software installation procedure, as is well known in the art. In another embodiment, at least a portion of the software instructions may also be downloaded over a cable, communication, and/or wireless connection. In other embodiments, the disclosure programs are a computer program propagated signal product embodied on a propagated signal on a propagation medium (e.g., a radio wave, an infrared wave, a laser wave, a sound wave, or an electrical wave propagated over a global network such as the Internet, or other network(s)).

In alternate embodiments, the propagated signal is an analog carrier wave or digital signal carried on the propagated medium. For example, the propagated signal may be a digitized signal propagated over a global network (e.g., the Internet), a telecommunications network, or other network (such as network 70 of FIG. 17). In one embodiment, the propagated signal is a signal that is transmitted over the propagation medium over a period of time, such as the instructions for a software application sent in packets over a network over a period of milliseconds, seconds, minutes, or longer. In another embodiment, the computer readable medium of computer program product 92 is a propagation medium that the computer system 50 may receive and read, such as by receiving the propagation medium and identifying a propagated signal embodied in the propagation medium, as described above for computer program propagated signal product. In other embodiments, the program product 92 may be implemented as a so-called Software as a Service (SaaS), or other installation or communication supporting end-users.

Embodiments or aspects thereof may be implemented in the form of hardware including but not limited to hardware circuitry, firmware, or software. If implemented in software, the software may be stored on any non-transient computer readable medium that is configured to enable a processor to load the software or subsets of instructions thereof. The processor then executes the instructions and is configured to operate or cause an apparatus to operate in a manner as described herein.

Further, hardware, firmware, software, routines, or instructions may be described herein as performing certain actions and/or functions of the data processors. However, it should be appreciated that such descriptions contained herein are merely for convenience and that such actions in fact result from computing devices, processors, controllers, or other devices executing the firmware, software, routines, instructions, etc.

It should be understood that the flow diagrams, block diagrams, and network diagrams may include more or fewer elements, be arranged differently, or be represented differently. But it further should be understood that certain implementations may dictate the block and network diagrams and the number of block and network diagrams illustrating the execution of the embodiments be implemented in a particular way.

Accordingly, further embodiments may also be implemented in a variety of computer architectures, physical, virtual, cloud computers, and/or some combination thereof, and, thus, the data processors described herein are intended for purposes of illustration only and not as a limitation of the embodiments.

The teachings of all patents, published applications, and references cited herein are incorporated by reference in their entirety.

While example embodiments have been particularly shown and described, it will be understood by those skilled in the art that various changes in form and details may be made therein without departing from the scope of the embodiments encompassed by the appended claims.

1. A computer-implemented method for generating a resilience analysis of a real-world system, the method comprising:
constructing a network graph representing a real-world system for providing a plurality of functions by:
generating a plurality of nodes corresponding to the plurality of functions; and
generating a plurality of edges, each of the plurality of edges (i) linking a pair of the plurality of nodes and (ii) representing a causal dependency between respective functions corresponding to the pair of the plurality of nodes;
simulating, via a first model, based on the network graph, one or more configurations of the real-world system by:
modifying a configuration of: (i) at least one function corresponding to a node of the plurality of nodes or (ii) at least one causal dependency corresponding to an edge of the plurality of edges; and
generating, via the first model, based on the simulating, a resilience analysis of the real-world system.

2. The method of claim 1, wherein the first model is trained with data representing one or more real-world systems having common elements to the real-world system.

3. The method of claim 1, further comprising:
identifying, via the first model, based on the resilience analysis, one or more modifications to the real-world system to improve resilience.

4. The method of claim 3, further comprising generating a visualization of at least one of the one or more modifications to the real-world system.

5. The method of claim 3, wherein the one or more modifications to the real-world system are identified based on user-defined criteria including at least one of: (i) cost and (ii) prioritizing one or more functions of the plurality of functions.

6. The method of claim 5, further comprising:
determining, based on the user-defined criteria, a prioritized sequence of the one or more modifications to the real-world system.

7. The method of claim 3, further comprising:
causing at least one of the one or more modifications to be applied to the real-world system.

8. The method of claim 7, wherein the one or more modifications include at least one of: (i) a service-level modification and (ii) an asset-level modification.

9. The method of claim 1, wherein generating, via the first model, based on the simulating, the resilience analysis of the real-world system includes:
determining, via the first model, one or more resilience scores representing at least one of: (i) a capacity of the real-world system to absorb the failure of the at least one of the plurality of functions, (ii) a capacity of the real-world system to recover from the failure of the at least one of the plurality of functions, and (iii) a capacity of the real-world system to adapt to the failure of the at least one of the plurality of functions.

10. The method of claim 1, wherein the plurality of nodes represents one or more resources associated with the plurality of functions, the one or more resources including at least one of: (i) physical resources, (ii) digital resources, and (iii) personnel resources.

11. The method of claim 1, further comprising:
identifying, via a second model: (i) one or more external drivers and (ii) one or more causal dependencies between the one or more external drivers and one or more corresponding functions of the plurality of functions;
generating one or more nodes corresponding to the one or more external drivers identified;
generating one or more edges corresponding to the one or more causal dependencies identified; and
modifying the network graph to incorporate the one or more nodes generated and the one or more edges generated.

12. The method of claim 11, wherein the one or more external drivers include one or more of: (i) environmental-based drivers, (ii) transport-based drivers, (iii) econometric drivers, (iv) energy-based drivers, (v) cyber-based drivers, and (vi) commodity-based drivers.

13. The method of claim 11, wherein the identifying comprises executing, via the second model, one or more search functions on one or more respective causal networks contained in a repository.

14. The method of claim 1, wherein at least one of the one or more configurations of the real-world system includes a disruption to a first function of the plurality of functions, the disruption causing a failure of a second function of the plurality of functions.

15. The method of claim 1, wherein at least one of the one or more configurations of the real-world system includes one or more distinct operational conditions of the real-world system including one or more of: (i) a system workload and (ii) demand for a function.

16. The method of claim 1, wherein the first model includes one or more of: (i) a system dynamics model, (ii) a graph theory model, (iii) a Bayesian network model, and (iv) an agent-based model.

17. The method of claim 1, wherein the first model includes at least one of a machine learning (ML) model and an artificial intelligence (AI) model.

18. The method of claim 1, wherein generating the plurality of nodes corresponding to the plurality of functions comprises:
parameterizing respective functions of the plurality of functions corresponding to the plurality of nodes.

19. The method of claim 1, further comprising:
generating, via a third model, based on the resilience analysis, one or more performance metrics for the real-world system; and
identifying, via the third model, based on the one or more performance metrics, at least one critical component of the real-world system.

20. A computer-based system for generating a resilience analysis of a real-world system, the computer-based system comprising:
a processor; and
a memory with computer code instructions stored thereon, the processor and the memory, with the computer code instructions, being configured to cause the computer-based system to:
construct a network graph representing a real-world system for providing a plurality of functions by:
generating a plurality of nodes corresponding to the plurality of functions; and
generating a plurality of edges, each of the plurality of edges (i) linking a pair of the plurality of nodes and (ii) representing a causal dependency between respective functions corresponding to the pair of the plurality of nodes;
simulate, via a first model, based on the network graph, one or more configurations of the real-world system by:
modifying a configuration of: (i) at least one function corresponding to a node of the plurality of nodes or (ii) at least one causal dependency corresponding to an edge of the plurality of edges; and
generate, via the first model, based on the simulating, a resilience analysis of the real-world system.

21. A non-transitory computer program product comprising a computer-readable medium with computer code instructions stored thereon, the computer code instructions being configured, when executed by a processor, to cause an apparatus associated with the processor to:
construct a network graph representing a real-world system for providing a plurality of functions by:
generating a plurality of nodes corresponding to the plurality of functions; and
generating a plurality of edges, each of the plurality of edges (i) linking a pair of the plurality of nodes and (ii) representing a causal dependency between respective functions corresponding to the pair of the plurality of nodes;
simulate, via a first model, based on the network graph, one or more configurations of the real-world system by:
modifying a configuration of: (i) at least one function corresponding to a node of the plurality of nodes or (ii) at least one causal dependency corresponding to an edge of the plurality of edges; and
generate, via the first model, based on the simulating, a resilience analysis of the real-world system.
